(19) United States
(12) Patent Application Publication
(10) Pub. No.: US 2003/0003767 A1
(43) Pub. Date: Jan. 2, 2003

(54) High throughput hybrid deposition system and method using the same

(75) Inventors: Steven Kim, Harrington Park, NJ (US); Seungdeok Kim, Moonachie, NJ (US)

Correspondence Address: MORGAN LEWIS & BOCKIUS LLP, 1111 PENNSYLVANIA AVENUE NW, WASHINGTON, DC, 20004, US

(73) Assignee: PLASMION CORPORATION

(21) Appl. No.: 10/046,241

(22) Filed: Jan. 16, 2002

Related U.S. Application Data
(60) Provisional application No. 60/301,478, filed on Jun. 29, 2001.

(51) Int. Cl. H01L 21/31; H01L 21/469; C23C 16/00

(52) U.S. Cl. 438/763; 118/719

(57) ABSTRACT

A deposition system includes at least one first load lock chamber, at least one deposition chamber attached to the first load lock chamber, the at least one deposition chamber having a plurality of deposition sources disposed circumferentially about sidewalls of the deposition chamber, at least one second load lock chamber attached to the deposition chamber, a plurality of gas inlet ports and vacuum line ports disposed on each of the first and second load lock chambers and the deposition chamber, and a plurality of rotatable deposition pallets, at least one deposition pallet is disposed within the deposition chamber and at least one deposition pallet is disposed in one of the first and second load lock chambers, wherein the at least one deposition pallet disposed in one of the first and second load lock chambers laterally shifts into the deposition chamber when the at least one deposition pallet disposed in the deposition chamber laterally shifts from the deposition chamber into another one of the first and second load lock chambers.

This application claims the benefit of a provisional application, entitled “High Throughput In-Line and Batch Hybrid Coating,” which was filed on Jun. 29, 2001, and assigned Provisional Application No. 60/301,478, which is hereby incorporated by reference.

### BACKGROUND OF THE INVENTION

1. Field of the Invention

The present invention relates to a thin film deposition system, a deposition device and a deposition method, and more particularly, to a hybrid in-line and batch type deposition system, a deposition pallet and deposition method using the same.

2. Description of Related Art

In general, deposition systems used for depositing materials onto semiconductor substrates are classified into two categories: in-line type and batch type. In-line type deposition systems are used for relatively large sized substrate such as glass and sapphire, for example. FIG. 1 shows a conventional in-line type deposition system. In FIG. 1, substrates 1 are loaded onto a linear conveyor mechanism disposed within a first load lock chamber 2. After loading, the substrates 1 are transferred into a deposition chamber 3 containing a linear array of deposition sources 5. As the substrates 1 travel through the deposition chamber 3 on the linear conveyor mechanism, each of the deposition sources 5 coats surfaces of the substrates 1 with a thin film. Once the substrates 1 have completely traversed the deposition chamber 3, the now-processed substrates 1 are transferred to a second load lock chamber 4 for unloading. Accordingly, exposed surfaces of the now-processed substrates 2 include at least one layer of deposited material. Thus, the in-line type deposition system performs a continuous coating process, thereby providing a high throughput. However, coating uniformity along the traversing direction is dependent upon the linear conveyor mechanism and coating uniformity along a width direction orthogonal to the traversing direction is dependent upon the deposition source. Accordingly, variations in either the linear conveyor mechanism and/or the deposition sources can lead to non-uniformity of the deposited material upon the substrates 5.

FIGS. 2A and 2B show a conventional batch type deposition system. In FIGS. 2A and 2B, substrates 15 are each disposed on circumferential portions of a substrate holder 14. After the substrates 15 are loaded onto the substrate holder 14, the substrate holder 14 is placed into a deposition chamber 17. Multiple deposition sources 18 are circumferentially disposed along sidewalls of the deposition chamber 17. In general, each of the multiple deposition sources 18 deposits the same material by sputtering, for example. Once the substrate holder 14 is placed into the deposition chamber 17, the substrate holder 14 rotates about a central axis providing uniform deposition of material on exposed surfaces of each of the substrates 15. Furthermore, each of the substrates 15 loaded on the substrate holder 14 may have a corresponding planetary motion in addition to, or instead of, the rotational motion of the substrate holder 14. Thus, the batch type deposition system provides uniform material deposition simultaneously on larger numbers of substrates.

However, in contrast to in-line type deposition systems, the batch type deposition system does not operate in a continuous mode. Specifically, once deposition processing of the substrates 15 on the substrate holder 17 is completed, the substrate holder 17 must be unload and replaced with a new substrate holder having unprocessed substrates. The unloading and replacing of substrates creates significant amounts of time in which the deposition chamber is not in use, i.e. “down-time,” and results in a relatively low throughput. Furthermore, the batch type deposition system allows for the deposition of only a single type of material. Thus, deposition of multiple layers of different materials is not possible.

### SUMMARY OF THE INVENTION

Accordingly, the present invention is directed to a high throughput in-line and batch hybrid coating system that substantially obviates one or more of problems due to limitations and disadvantages of the related art.

An object of the present invention is to provide a high throughput hybrid deposition system and deposition process that utilizes both continuous and uniform coating of large numbers of substrates.

Another object of the present invention is to provide a high throughput hybrid deposition system and deposition method using a high throughput hybrid deposition system that utilizes continuously and uniform coating of different materials onto large numbers of substrates.

Another object of the present invention is to provide a deposition pallet device that allows for deposition of materials on multiple sides of each individual substrate.

Additional features and advantages of the invention will be set forth in the description that follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a deposition system includes at least one first load lock chamber, at least one deposition chamber attached to the first load lock chamber, the at least one deposition chamber having a plurality of deposition sources disposed circumferentially about sidewalls of the deposition chamber, at least one second load lock chamber attached to the deposition chamber, a plurality of gas inlet ports and vacuum line ports disposed on each of the first and second load lock chambers and the deposition chamber, and a plurality of rotatable deposition pallets, at least one deposition pallet is disposed within the deposition chamber and at least one deposition pallet is disposed in one of the first and second load lock chambers, wherein the at least one deposition pallet disposed in one of the first and second load lock chambers laterally shifts into the deposition chamber when the at least one deposition pallet disposed in the deposition chamber laterally shifts from the deposition chamber into another one of the first and second load lock chambers.

In another aspect, a deposition system includes a first load lock chamber, a deposition chamber attached to the first load lock chamber via a first gate valve, the deposition chamber includes a plurality of deposition stages each stage includes a plurality of deposition sources disposed circumferentially about sidewalls of the deposition stage, a second load lock chamber attached to the deposition chamber via a second gate valve, and a plurality of rotatable deposition pallets, at least one deposition pallet is disposed within each of the deposition stages and at least one deposition pallet is disposed in the first load lock chamber, wherein the at least one deposition pallet disposed in the first load lock chamber laterally shifts into a first one of the plurality of deposition stages when a deposition pallet disposed in a last one of the plurality of deposition stages laterally shifts into the second load lock chamber.

In another aspect, a rotatable deposition pallet includes a deposition pallet rotator, an axial member having a first end connected to the deposition pallet rotator, a deposition frame member concentrically connected to the axial member, a substrate mounting member concentrically connected to the deposition frame member, the substrate mounting member having a plurality of sides, and a plurality of substrate platforms, wherein each of the substrate platforms are attached on at least one of the plurality of sides of the substrate mounting member.

In another aspect, a deposition method includes placing a first rotatable deposition pallet loaded with a first plurality of substrates into a first load lock portion of a deposition chamber, transferring the first rotatable deposition pallet from the first load lock portion to a deposition portion of the deposition chamber, transferring a second rotatable deposition pallet loaded with a second plurality of substrates processed in the deposition portion of the deposition chamber into a second load lock portion of the deposition chamber, wherein the transferring of the first rotatable deposition pallet is performed simultaneously with the transferring of the second rotatable deposition pallet.

In another aspect, a deposition method includes placing a first rotatable deposition pallet loaded with a first plurality of substrates into a first load lock portion of a deposition chamber, transferring the first rotatable deposition pallet from the first load lock portion to a first one of a plurality of deposition stages of the deposition chamber, transferring a second rotatable deposition pallet loaded with a second plurality of substrates processed within each of the plurality of deposition stages from a last one of the plurality of deposition stages of the deposition chamber into a second load lock portion of the deposition chamber, wherein the transferring of the first rotatable deposition pallet is performed simultaneously with the transferring of the second rotatable deposition pallet.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a configuration of a conventional in-line type deposition system;

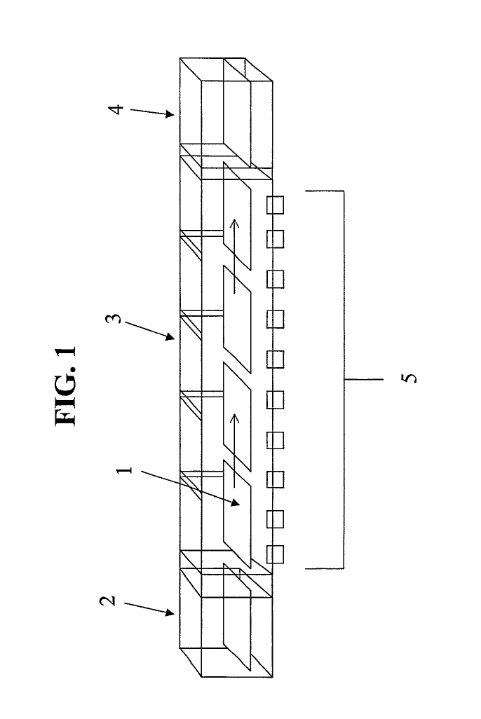

FIG. 2A shows a configuration of a conventional batch type deposition system, and FIG. 2B is a cross sectional view along line A-A′ of FIG. 2A;

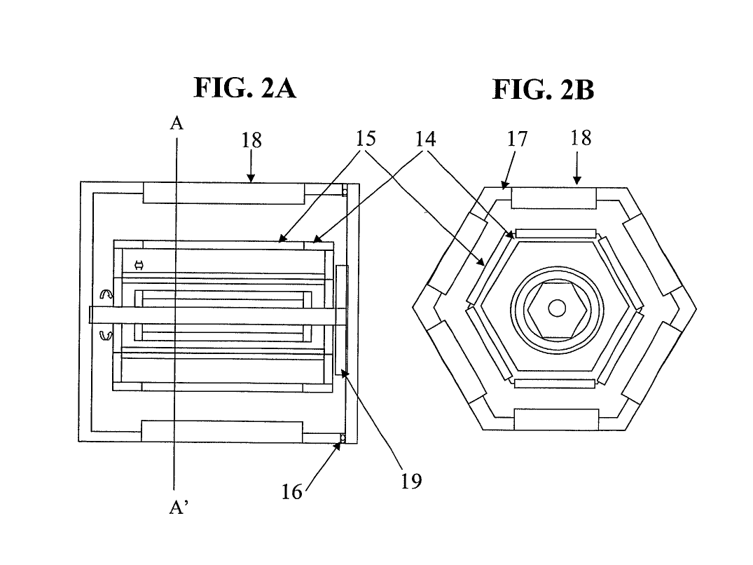

FIG. 3 is an exemplary hybrid deposition system according to the present invention;

FIG. 4 is another exemplary hybrid deposition system according to the present invention;

FIG. 5 is another exemplary hybrid deposition system according to the present invention; and

FIG. 6 is an exemplary deposition pallet according to the present invention.

### DETAILED DESCRIPTION OF ILLUSTRATED EMBODIMENTS

Reference will now be made in detail to illustrated embodiment of the present invention, examples of which are shown in the accompanying drawings. Wherever possible, the same reference numbers will be used throughout the drawings to refer to the same or like parts.

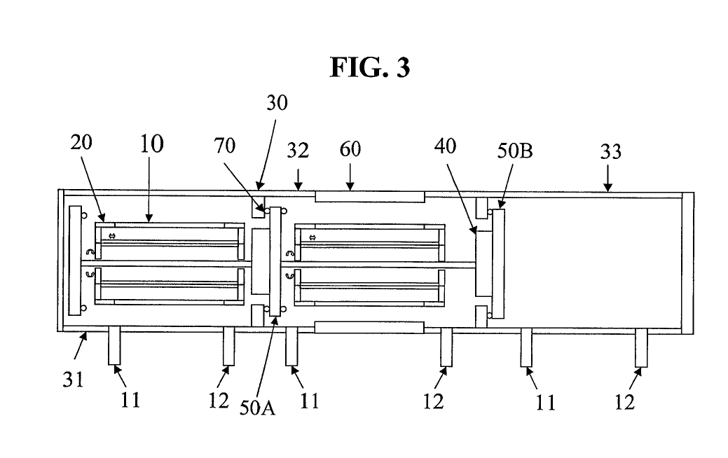

FIG. 3 is an exemplary hybrid deposition system according to the present invention. In FIG. 3, a plurality of individual substrates 10 is disposed on an outer face of a deposition pallet 20. The substrates 10 may be of any specific individual geometry and may be a combination of individual substrates of different geometries. Furthermore, the deposition pallet 20 may include any number of sides. The deposition pallet 20 is axial disposed on a shaft of a deposition pallet rotator 40 within a deposition chamber 30. The deposition pallet rotator 40 is connected to vacuum flanges 50A, 50B that include vacuum seals 70 disposed about the vacuum flanges 50A, 50B. The deposition chamber 30 includes a first load lock portion 31, a deposition portion 32, and a second load lock portion 33. The first and second lock portions 31, 33 and the deposition portion 32 each have both gas inlet ports 11 and vacuum line ports 12. The vacuum flange 50A disposed within the deposition portion 32 of the deposition chamber 30 may include vacuum seals 70 disposed on opposite sides of the vacuum flange 50A while the vacuum flanges 50B disposed within the first and second load lock portions 31, 33 of the deposition chamber 30 may include vacuums seals 70 on a single side of the respective first and second load lock portions 31, 33. Deposition sources 60 are circumferentially disposed along sidewalls of the deposition portion 32 of the deposition chamber 30. Since the deposition rate is dependent on the number of deposition sources 60, almost any number of deposition sources 60 may be used. Furthermore, although the deposition sources 60 are shown to be rectangular in cross section, almost any geometry may be implemented. Even further, deposition sources may be disposed in multiple “rings” about the sidewalls of the deposition portion 32.

In FIG. 3, the hybrid deposition system continuously deposits material onto each exposed surface of the substrates 10, thereby providing close to isotropic deposition. During operation of the hybrid deposition system, a deposition pallet 20 loaded with substrates 10 is placed onto deposition pallet rotator 40 in the first load lock portion 31, and the first and second load lock portions 31, 33 are sealed. Then, pressures of the first and second load lock portions 31, 33 are first reduced via the vacuum line ports 12 and then adjusted with gas via gas inlet ports 11 to match a pressure of the deposition portion 32. The deposition pallet rotator 40 and the deposition pallet 20 that is loaded with substrates 10 are laterally shifted from the first load lock portion 31 to inside the deposition portion 32. Simultaneously, the deposition pallet rotator 40 and the deposition pallet 20 loaded with processed substrates 10 residing in the deposition portion 32 are also laterally shifted from the deposition portion 32 and transferred into the second load lock portion 33. Once the deposition pallet rotator 40 and the deposition pallet 20 loaded with substrates 10 are completely inside of the deposition portion 32, the deposition portion 32 is sealed via the vacuum seals 70. Then, the deposition pallet rotator 40 rotates the deposition pallet 20 and the deposition of material onto each exposed surface of the substrates 10 begins. Meanwhile, the second load lock portion 33 is brought to ambient pressure and opened. The deposition pallet rotator 40 with the deposition pallet 20 loaded with processed substrates 10 is stopped and the deposition pallet 20 is removed. Then, a new deposition pallet 20 loaded with substrates 10 is placed on the deposition pallet rotator 40 in the second load lock portion 33 and awaits lateral transfer into the deposition portion 32 for deposition processing. This repetitive process of loading and unloading deposition pallets 20 from the first and second load locks 31, 33 continues until the desired number of substrates and/or deposition pallets are processed.

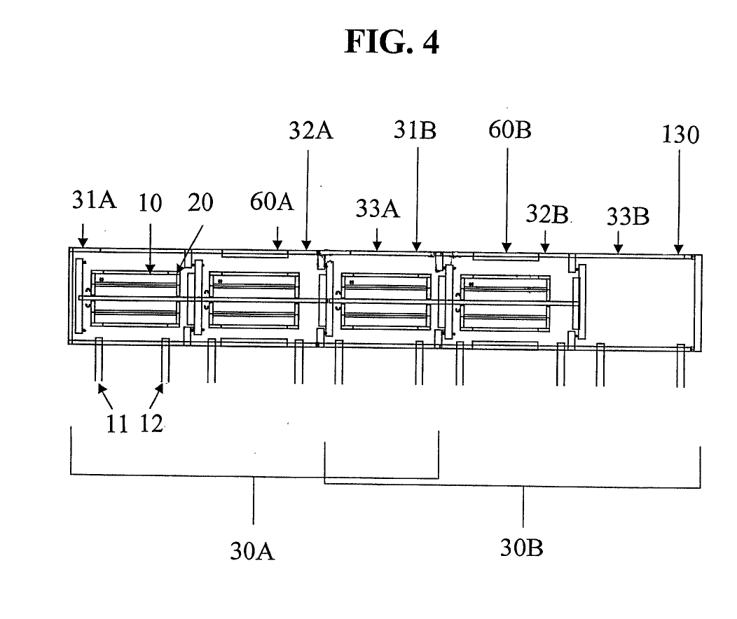

FIG. 4 shows another exemplary hybrid deposition system according to the present invention. In FIG. 4, a dual hybrid deposition system is shown which incorporates two of the single hybrid deposition systems shown in FIG. 3, thereby effectively doubling throughput of the system. The dual hybrid deposition system includes a deposition chamber 130 having a first deposition chamber 30A and a second deposition chamber 30B. The first deposition chamber 30A includes a first load lock portion 31A, a deposition portion 32A, and a second load lock portion 33A. The deposition portion 32A includes deposition sources 60A that are circumferentially disposed along sidewalls of the deposition portion 32A. The second deposition chamber 30B includes a first load lock portion 31B, a deposition portion 32B, and a second load lock portion 33B. The deposition portion 32B includes deposition sources 60B that are circumferentially disposed along sidewalls of the deposition portion 32B.

In FIG. 4, the second load lock portion 33A of the first deposition chamber 30A and the first load lock portion 31B of the second deposition chamber 30B are coincide, thereby providing the dual hybrid deposition system with the ability to perform in-line type and batch type deposition of multiple materials onto the substrates 10. For example, the deposition portion 60A may deposit a first material “A” onto the substrates 10 of the deposition pallet 20. After the substrates 10 are coated with the first material “A,” the deposition pallet 20 may be removed from the second load lock portion 33A or laterally transferred into the deposition portion 60B for deposition of a second material “B.” Accordingly, the number of individual hybrid deposition systems may be increased to process the substrates 10 with any number of materials, or with any number of combinations of materials. For instance, if three individual single hybrid deposition systems where implemented, the substrates 10 may be coated with a first material “A” in a first deposition portion 32A. Then, if desired, the substrates may forego deposition of a second material “B” in a second deposition portion 32B and proceed to a deposition of a third material “C” in a third deposition portion 32C (not shown). Additionally, the substrates 10 may be returned to the first deposition portion 32A for additional deposition of the material “A,” thereby forming substrates with a material layer combination of “A-C-A.”

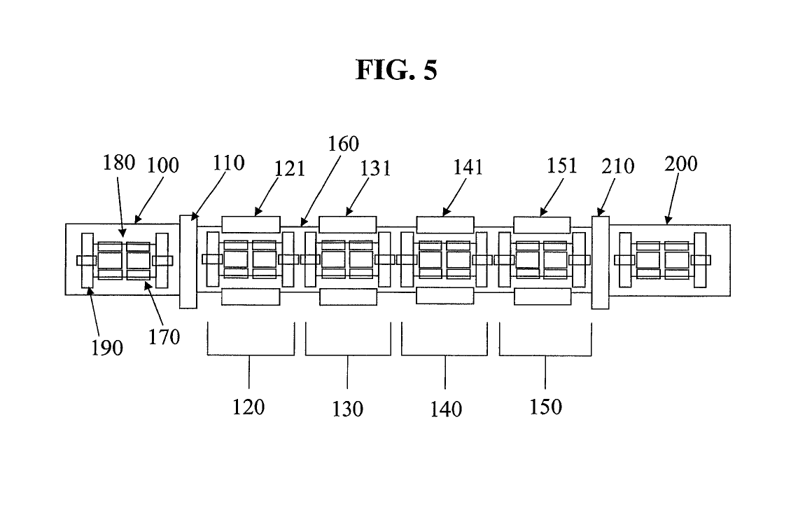

FIG. 5 shows another exemplary hybrid deposition system according to the present invention. In FIG. 5, a continuous in-line batch type deposition system is shown where separate deposition portions are placed back-to-back, thereby providing both in-line and batch type deposition processing. The continuous batch type deposition system includes a deposition chamber 160, a first load lock chamber 100, a second load lock chamber 200, a first gate valve 110, and a second gate valve 210. The deposition chamber 160 includes first 120, second 130, third 140, and fourth 150 deposition stages. Each of the deposition stages 120, 130, 140, 150 includes a plurality of deposition sources 121, 131, 141, 151, circumferentially disposed about sidewalls of each of the deposition stages, respectively. Although four deposition stages are shown, any number of deposition stages may be implemented to achieve the desired substrate processing. Each of the deposition sources may be the same as or different from any adjacent deposition stage. For example, the deposition sources 121 may deposit material “A” at deposition stage 120 and the deposition sources 131 may deposit material “B” at deposition stage 130. Alternatively, the deposition sources 121, 131 may deposit the same material “C” at both deposition stages 120, 130, respectively. Moreover, if the same material “C” is to be deposited at both deposition stages 120, 130, the deposition rates and/or conditions may be altered, thereby providing multiple layers of material “C” with each layer having different specific properties.

Similar to the dual hybrid deposition system shown in FIG. 4, the in-line batch type deposition system shown in FIG. 5 allows for continuous deposition of different materials onto substrates 170, thereby further increasing throughput of the system. Here, a substrate pallet 180 loaded with substrates 170 is placed into the first load lock chamber 100. The deposition pallet 180 includes a deposition pallet rotator 190 that may be disposed at opposing ends of the substrate pallet 180. Alternatively, a single deposition pallet rotator 190 may be disposed at either ends of the deposition pallet 180. The first and second load lock chambers 100, 200 are sealed and processed to match the ambient conditions of the deposition chamber 160. Then, the first and second gate valves 110, 210 are opened, the deposition pallet 180 loaded with substrates is transferred into the first stage 120 of the deposition chamber 160 for processing, the deposition pallet 180 loaded with now-processed substrates is transferred into the second load lock chamber 200, and the first and second gate valves 110, 210 are closed. The second load lock chamber 200 is opened and the deposition pallet 180 is removed from the deposition pallet rotator 190. Simultaneously, the first load lock chamber 100 is opened and a third deposition pallet loaded with substrates is placed into the first load lock chamber 100 to awaiting lateral transfer into the deposition chamber 160 for deposition processing.

Inside the first stage 120, the deposition pallet 180 is rotated via the deposition pallet rotator 190 and each exposed surface of the substrates 170 is coated with a first material of the first deposition stage sources 121. The deposition pallet 180 is then laterally transferred to a second deposition stage 130 where a second material of the second deposition stage sources 131 is deposited onto each exposed surface of the substrates 170. In a similar fashion, the deposition pallet 180 is then sequentially transferred to the third and fourth deposition stages 140, 150 where third and fourth materials of the third and fourth deposition stages sources 141, 151 are respectively deposited onto each exposed surface of the substrates 170 of the deposition pallet 180. Once the substrates 170 have been processed through each of the deposition stages, the deposition pallet 180 is laterally transferred to the second load lock chamber 200 via a gate valve 120, which is brought to the ambient conditions of the deposition chamber 160. Then, the gate valve 120 is closed, the second load lock chamber 200 is opened, and the deposition pallet 180 is removed from the second load lock chamber 200.

During operation of the in-line batch type deposition system shown in FIG. 5, the deposition pallets 180 may laterally traverse the deposition chamber 160 in a stepwise manner or may traverse the deposition chamber 160 in a continuous, non-stepwise manner.

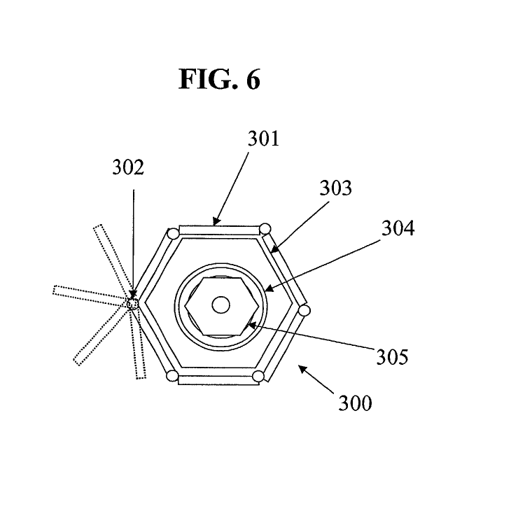

FIG. 6 shows an exemplary deposition pallet 300 according to the present invention. In FIG. 6, a deposition pallet 300 includes a deposition pallet mounting member 303 upon which substrate platforms 301 reside, a deposition pallet frame member 304 attached to the deposition pallet mounting member 303, and a substrate pallet axial member 305 attached to the deposition pallet frame member 304 and to a deposition pallet rotator (not shown). Each of the substrate platforms 301 may have a first side portion attached to the deposition pallet 300 via a hinge assembly 302. Substrates (not shown) may be individually attached to the substrate platforms 301 prior to deposition processing. Alternatively, the substrates may have hinge assemblies integrally attached thereto such that use of the substrate platforms 301 may not be necessary.

During deposition processing, the substrate platforms 301 are securely attached to the deposition pallet 300 via individual latching mechanisms (not shown). Before, during and/or after the deposition processing, the individual latching mechanisms may be simultaneously released and the substrate platforms 301 may be sequentially rotated about each of the hinge assemblies 302, thereby exposing opposite sides of the substrates to the deposition processing and decreasing processing time. Alternatively, the deposition pallet 300 may exclude one or more of the substrate platforms 301 such that each substrate platform 301 may be sequentially rotated about corresponding hinge assemblies 302, thereby selectively exposing opposite sides of specific substrates to the deposition processing.

In FIG. 6, although the exemplary deposition pallet 300 is shown having six platform sides, any number of platform sides may be implemented. In addition, the deposition pallet 300 may include multiple substrate platforms 301 disposed on a single platform side, thereby accommodating substrates of different sizes and geometric configurations. Furthermore, each of the platform sides may have different sizes and geometric configurations.

It will be apparent to those skilled in the art that various modifications and variations can be made in the capacitor and the manufacturing method thereof of the present invention without departing from the spirit or scope of the inventions. Thus, it is intended that the present invention cover the modifications and variations of this invention provided they come within the scope of the appended claims and their equivalents.

What is claimed is:

1. A deposition apparatus, comprising:
at least one first load lock chamber;
at least one deposition chamber attached to the first load lock chamber, the at least one deposition chamber having a plurality of deposition sources disposed circumferentially about sidewalls of the deposition chamber;
at least one second load lock chamber attached to the deposition chamber;
a plurality of gas inlet ports and vacuum line ports disposed on each of the first and second load lock chambers and the deposition chamber; and
a plurality of rotatable deposition pallets, at least one deposition pallet is disposed within the deposition chamber and at least one deposition pallet is disposed in one of the first and second load lock chambers,
wherein the at least one deposition pallet disposed in one of the first and second load lock chambers laterally shifts into the deposition chamber when the at least one deposition pallet disposed in the deposition chamber laterally shifts from the deposition chamber into another one of the first and second load lock chambers.

2. The deposition apparatus according to claim 1, wherein each of the plurality of deposition pallets includes a deposition pallet rotator that rotates the deposition pallet about a central axis during deposition processing within the deposition chamber.

3. The deposition apparatus according to claim 1, wherein each of the plurality of deposition pallets includes a vacuum flange attached to a deposition pallet rotator.

4. The deposition apparatus according to claim 1, wherein each of the plurality of deposition pallets includes a plurality of deposition sides with at least one substrate removable attached to each of the plurality of deposition sides via a substrate platform.

5. A deposition apparatus, comprising:
a first load lock chamber;
a deposition chamber attached to the first load lock chamber via a first gate valve, the deposition chamber includes a plurality of deposition stages each stage includes a plurality of deposition sources disposed circumferentially about sidewalls of the deposition stage;
a second load lock chamber attached to the deposition chamber via a second gate valve; and
a plurality of rotatable deposition pallets, at least one deposition pallet is disposed within each of the deposition stages and at least one deposition pallet is disposed in the first load lock chamber,
wherein the at least one deposition pallet disposed in the first load lock chamber laterally shifts into a first one of the plurality of deposition stages when a deposition pallet disposed in a last one of the plurality of deposition stages laterally shifts into the second load lock chamber.

6. The deposition apparatus according to claim 5, wherein each of the plurality of deposition pallets includes at least one deposition pallet rotator that rotates the deposition pallet during deposition processing.

7. The deposition apparatus according to claim 5, wherein each of the plurality of deposition pallets includes a plurality of deposition sides with at least one substrate removable attached to each of the plurality of deposition sides via a substrate platform.

8. A rotatable deposition pallet, comprising:
a deposition pallet rotator;
an axial member having a first end connected to the deposition pallet rotator;
a deposition frame member concentrically connected to the axial member;
a substrate mounting member concentrically connected to the substrate frame member, the substrate mounting member having a plurality of sides; and
a plurality of substrate platforms;
wherein each of the substrate platforms are removably attached on at least one of the plurality of sides of the substrate mounting member.

9. The rotatable deposition pallet according to claim 8, wherein each of the substrate platforms are movably attached on the at least one of the plurality of sides of the substrate mounting member via a hinge mechanism.

10. The rotatable deposition pallet according to claim 8, wherein each of the substrate platforms are movably attached to the at least one of the plurality of sides of the substrate mounting member via a latch mechanism.

11. The rotatable deposition pallet according to claim 8, wherein each of substrate platforms are movably attached to the at least one of the plurality of sides of the substrate mounting member via a hinge mechanism and a latch mechanism.

12. The rotatable deposition pallet according to claim 8, further comprising a vacuum flange attached to one side of the deposition pallet rotator.

13. A deposition method, comprising:
placing a first rotatable deposition pallet loaded with a first plurality of substrates into a first load lock portion of a deposition chamber;
transferring the first rotatable deposition pallet from the first load lock portion to a deposition portion of the deposition chamber,
transferring a second rotatable deposition pallet loaded with a second plurality of substrates processed in the deposition portion of the deposition chamber into a second load lock portion of the deposition chamber,
wherein the transferring of the first rotatable deposition pallet is performed simultaneously with the transferring of the second rotatable deposition pallet.

14. The deposition method according to claim 13, further comprising:
continuously rotating the first deposition pallet after transferring the first deposition pallet into the deposition portion of the deposition chamber; and
depositing material from first deposition sources circumferentially disposed about sidewalls of the deposition portion of the deposition chamber onto first surfaces of each of the first plurality of substrates.

15. The deposition method according to claim 14, further comprising:
removing the second deposition pallet from the second load lock portion of the deposition chamber; and
placing a third rotatable deposition pallet loaded with a third plurality of substrates into the first load lock portion of the deposition chamber,
wherein the removing of the second deposition pallet is performed simultaneously with the placing of the third rotatable deposition pallet.

16. The deposition method according to claim 14, further comprising:
rotating the first plurality of substrates about a hinged mechanism of the first deposition pallet during the depositing of material.

17. A deposition method, comprising:
placing a first rotatable deposition pallet loaded with a first plurality of substrates into a first load lock portion of a deposition chamber;
transferring the first rotatable deposition pallet from the first load lock portion to a first one of a plurality of deposition stages of the deposition chamber,
transferring a second rotatable deposition pallet loaded with a second plurality of substrates processed within each of the plurality of deposition stages from a last one of the plurality of deposition stages of the deposition chamber into a second load lock portion of the deposition chamber,
wherein the transferring of the first rotatable deposition pallet is performed simultaneously with the transferring of the second rotatable deposition pallet.

18. The deposition method according to claim 17, further comprising:
continuously rotating the first deposition pallet after the transferring of the first deposition pallet into the first deposition stage; and
depositing material from first deposition sources circumferentially disposed about sidewalls of the first deposition stage onto first surfaces of each of the first plurality of substrates.

19. The deposition method according to claim 18, further comprising:
removing the second deposition pallet from the second load lock portion of the deposition chamber; and
placing a third rotatable deposition pallet loaded with a third plurality of substrates into the first load lock portion of the deposition chamber,
wherein the removing of the second deposition pallet is performed simultaneously with the placing of the third rotatable deposition pallet.

20. The deposition method according to claim 18, further comprising:
rotating the first plurality of substrates about a hinged mechanism of the first deposition pallet during the step of depositing material.
